(19) United States
(12) Patent Application Publication
(10) Pub. No.: US 2022/0182021 A1
(43) Pub. Date: Jun. 9, 2022

(54) THIN FILM TRANSISTOR-BASED BOOTSTRAP STRUCTURE AMPLIFIER AND CHIP

(71) Applicant: SOUTH CHINA UNIVERSITY OF TECHNOLOGY, Guangzhou (CN)

(72) Inventors: Rongsheng CHEN, Guangzhou (CN); Houbo FAN, Guangzhou (CN); Guoyuan LI, Guangzhou (CN); Yuming XU, Guangzhou (CN); Yuning QIN, Guangzhou (CN); Zhaohui WU, Guangzhou (CN); Bin LI, Guangzhou (CN)

(21) Appl. No.: 17/593,844

(22) PCT Filed: Dec. 31, 2019
(86) PCT No.: PCT/CN2019/130416

§ 371 Date: Sep. 25, 2021

(30) Foreign Application Priority Data
Apr. 24, 2019 (CN) 201910331863.X

(51) Int. Cl. H03F 1/34; H03G 3/30

(52) U.S. Cl. CPC H03F 1/342; H03G 3/30

(57) ABSTRACT

The present disclosure discloses a thin film transistor (TFT)-based bootstrap structure amplifier, and a chip. The amplifier includes an input circuit, an output buffer, and several bootstrap structure units. The bootstrap structure units include a TFT and a capacitor. The drain and the gate of the TFT are both connected to the same voltage node. The source of the TFT is connected to one end of the capacitor. The other end of the capacitor is connected to an output signal node. The output buffer is formed by connecting the sources and drains of several TFTs in series. Two ends of the output buffer are respectively connected to an input voltage node and an output signal node. The source of the TFT in each bootstrap structure unit is connected to the gates of the TFTs in one output buffer. The input circuit includes an input signal node, the output signal node, and a grounding node. The present disclosure can increase circuit gain and have a simple structure and low fabrication cost. The present disclosure can be widely applied to the field of integrated circuits.

### TECHNICAL FIELD

The present disclosure relates to the field of integrated circuits, and particularly relates to a thin film transistor-based bootstrap structure amplifier and a chip.

### BACKGROUND

A TFT (Thin Film Transistor) has the advantages of low fabrication cost, good transparency, and can be fabricated on a flexible substrate. A TFT process-based high gain amplifier has a wide application prospect to wearable electronic equipment, radio frequency labels, biosensors, and other fields.

Due to the lack of a commercial device model such as a CMOS (complementary metal-oxide-semiconductor) and a complete process library for the TFT, the design and simulation of a TFT circuit are facing considerable challenges. In addition, the metal oxide thin film transistor process usually can only manufacture an n-type device. The lack of a p-type TFT which is a complementary device makes the TFT circuit usually have a relatively large leakage current in a steady-state, which further causes the design of a high-gain broadband amplifier circuit to face challenges. The gains of existing TFT process-based amplifiers are generally not high, and difficultly meet the needs of different occasions of various fields.

### SUMMARY

In view of this, the embodiments of the present disclosure aim to provide a thin film transistor (TFT)-based bootstrap structure amplifier and a chip. The invention has a simple circuit structure and can realize a high gain.

In a first aspect, the present disclosure provides a TFT-based bootstrap structure amplifier, including an input circuit, an output buffer, and several bootstrap structure units. The bootstrap structure units include a TFT and a capacitor. The drain and gate of the TFT are both connected to the same voltage node. The source of the TFT is connected to one end of the capacitor. The other end of the capacitor is connected to an output signal node. The output buffer is formed by connecting several TFTs in series. Two ends of the output buffer are respectively connected to an input voltage node and an output signal node. The source of the TFT in each bootstrap structure unit is connected to the gate of the TFT in one output buffer. The input circuit includes an input signal node, the output signal node, and a grounding node.

Preferably, the TFTs are all n-type TFTs.

Preferably, the TFTs in the bootstrap structure units are in switched-off states during operation.

Preferably, the input circuit is composed of a common-source common-gate circuit.

Preferably, the input circuit includes two n-type TFTs.

Preferably, the two n-type TFTs of the input circuit are both in a saturation region during operation.

Preferably, the amplifier includes first to fourth bootstrap structure units, and the output buffer includes four TFTs.

Preferably, a specific circuit of the TFT-based bootstrap structure amplifier is as follows.

The input circuit is composed of a first TFT and a second TFT. The source of the first TFT is connected to the grounding node; the drain of the first thin film transistor is connected to the source of the second TFT; the drain of the second TFT is connected to the output signal node; the gate of the first TFT is connected to the input signal node; the gate of the second TFT is connected to a bias voltage node;

the output buffer is composed of a third TFT, a fourth TFT, a fifth TFT, and a sixth TFT; the drain of the sixth TFT is connected to the input voltage node; the source of the sixth TFT is connected to the drain of the fifth TFT; the source of the fifth TFT is connected to the drain of the fourth TFT; the source of the fourth TFT is connected to the drain of the third TFT; the source of the third TFT is connected to the output signal node;

the first bootstrap structure unit is composed of a seventh TFT and a first capacitor; the drain and the gate of the seventh TFT are both connected to a first bias voltage node; the source of the seventh TFT is connected to the gate of the third TFT and one end of the first capacitor; the other end of the first capacitor is connected to the output signal node;

the second bootstrap structure unit is composed of an eighth TFT and a second capacitor; the drain and the gate of the eighth TFT are both connected to a second bias voltage node; the source of the eighth TFT is connected to the gate of the fourth TFT and one end of a second capacitor; the other end of the second capacitor is connected to the output signal node;

the third bootstrap structure unit is composed of a ninth TFT and a third capacitor; the drain and the gate of the ninth TFT are both connected to a second bias voltage node; the source of the ninth TFT is connected to the gate of the fifth TFT and one end of a third capacitor; the other end of the third capacitor is connected to the output signal node;

the fourth bootstrap structure unit is composed of a tenth TFT and a fourth capacitor; the drain and the gate of the tenth TFT are both connected to a fourth bias voltage node; the source of the tenth TFT is connected to the gate of the sixth TFT and one end of a fourth capacitor; the other end of the fourth capacitor is connected to the output signal node.

In a second aspect, the present disclosure provides a chip, including a package and the above-mentioned TFT-based bootstrap structure amplifier. The TFT-based bootstrap structure amplifier is packaged in the package.

Implementation of the embodiments of the present disclosure has the following beneficial effects: according to the TFT-based bootstrap structure amplifier provided by the embodiments of the present disclosure, the drains and gates of the TFTs of the bootstrap structure units are all connected to the same voltage node; the sources of the TFTs of the bootstrap structure units are connected to the capacitors and the gates of the TFTs in the output buffer; the other ends of the capacitors are connected to the output signal node. It can be seen that the amplifier increases the voltage through the bootstrap structure units and forms a feedback loop with the output buffer, to increase the voltage of the output buffer, thus increasing the circuit gain. This circuit has a simple structure, low fabrication cost, and wide application range.

### BRIEF DESCRIPTION OF THE DRAWINGS

FIG. 1 is a circuit module block diagram of a thin film transistor (TFT)-based bootstrap structure amplifier provided by the embodiments of the present disclosure;

FIG. 2 is a schematic circuit diagram of a TFT-based bootstrap structure amplifier provided by the embodiments of the present disclosure;

FIG. 3 is a schematic circuit diagram of a bootstrap structure unit of a TFT-based bootstrap structure amplifier provided by the embodiments of the present disclosure;

FIG. 4 is a schematic circuit diagram of an output buffer of a TFT-based bootstrap structure amplifier provided by the embodiments of the present disclosure;

FIG. 5 is a schematic circuit diagram of an input circuit of a TFT-based bootstrap structure amplifier provided by the embodiments of the present disclosure;

FIG. 6 is a schematic diagram of a simulation result of a TFT-based bootstrap structure amplifier provided by the embodiments of the present disclosure; and

FIG. 7 is a schematic diagram of another simulation result of a TFT-based bootstrap structure amplifier provided by the embodiments of the present disclosure.

### DETAILED DESCRIPTION OF THE EMBODIMENTS

The present disclosure is further described in detail below in combination with the accompanying drawings and specific embodiments.

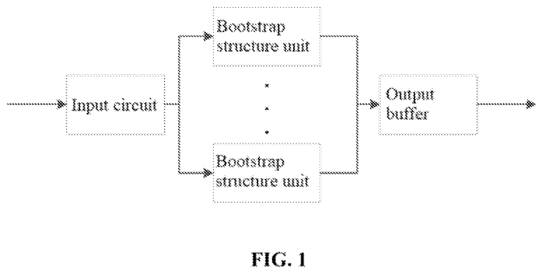

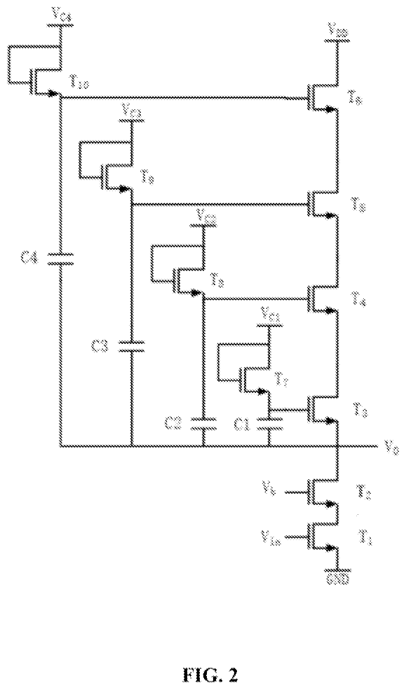

Referring to FIG. 1 and FIG. 2, the present embodiment provides a thin film transistor (TFT)-based bootstrap structure amplifier, including an input circuit, an output buffer, and several bootstrap structure units. The bootstrap structure units include a TFT and a capacitor. The drain and the gate of the TFT are both connected to the same voltage node. The source of the TFT is connected to one end of the capacitor. The other end of the capacitor is connected to an output signal node. The output buffer is formed by connecting several TFTs in series. Two ends of the output buffer are respectively connected to an input voltage node and an output signal node. The source of the TFT in each bootstrap structure unit is connected to the gate of the TFT in one output buffer. The input circuit includes an input signal node, the output signal node, and a grounding node.

Specifically, the input circuit includes the input signal node, the output signal node, and the grounding node. The number of the bootstrap structure units is the same as the number of the TFTs in the output buffer. The source of the transistor in one bootstrap structure unit is connected to the gate of one TFT in the output buffer. The bootstrap structure unit is a core circuit of the amplifier. Parameters of the TFTs in the bootstrap structure units are set according to a specific situation. Parameter settings of several TFTs are different.

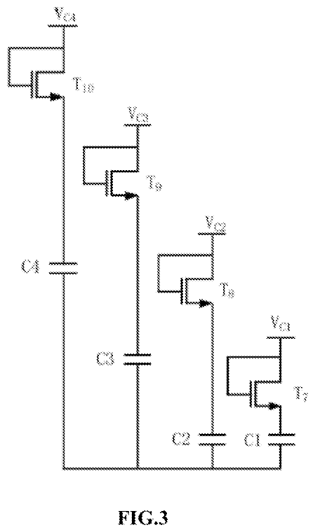

Referring to FIG. 3, the gates and drains of the TFTs in the bootstrap structure units are connected with each other and are connected to the same bias voltage node. A width-to-length ratio of each TFT is reasonably set so that the TFT is equivalent to serving as a load, and the bootstrap structure unit is equivalent to a bootstrap booster diode. The sources of the TFTs in the bootstrap structure units are connected to the capacitors, and the capacitors can store charges. When each capacitor is discharged, the voltage of the source of each TFT of the bootstrap structure unit is equal to a discharge voltage of the capacitor and a bias voltage, thus increasing the voltage of the source, increasing the circuit gain, and expanding the dynamic range of the circuit.

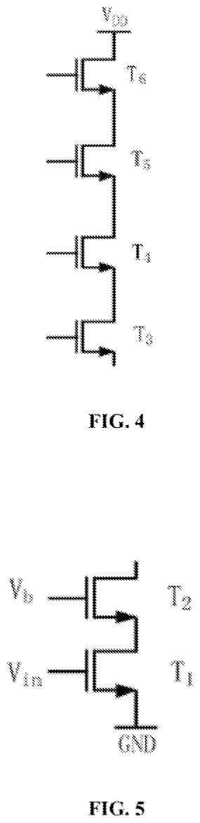

Referring to FIG. 4, the output buffer is formed by connecting the sources of the several TFTs to the drains in series. The two ends of the output buffer are respectively connected to the input voltage node and the output signal node. The source of the TFT in each bootstrap structure unit is connected to the gate of the TFT in one output buffer. The bootstrap structure unit has a booster effect, and the boosted voltage is connected to the gates of the TFTs in the output buffer through the sources of the TFTs in the bootstrap structure units to form a feedback loop so that the voltages of the gates of the TFTs in the output buffer are raised to increase the circuit gain. In addition, the output buffer can also improve the interference resistance of the circuit.

The drains and gates of the TFTs of the bootstrap structure units are all connected to the same voltage node; the sources of the TFTs of the bootstrap structure units are connected to the capacitors and the gates of the TFTs in the output buffer; and the other ends of the capacitors are connected to the output signal node. It can be seen that the amplifier increases the voltage through the bootstrap structure units and forms a feedback loop with the output buffer, so as to increase the voltage of the output buffer, thus increasing the circuit gain. This circuit has a simple structure, low fabrication cost, and wide application range.

Preferably, the TFTs are all n-type TFTs. The n-type TFTs can be realized by the current manufacturing process so that the n-type TFTs are convenient to use and low in cost.

Preferably, the TFTs in the bootstrap structure units are in switched-off states during operation. The TFT works in a cut-off region so that an active load of the circuit can be increased.

Preferably, the input circuit is composed of a common-source common-gate circuit. The common-source common-gate circuit has an amplification effect, and the bandwidth of the circuit can be increased.

Preferably, the input circuit includes two n-type TFTs. Referring to FIG. 5, in the input circuit, the source of one TFT is connected to the drain of the other TFT; the gate of the TFT connected to the grounding node is connected to the input signal node, and the gate of the other TFT is connected to the bias voltage node. Of course, as an alternative embodiment, the input circuit may also consist of a single TFT or may be formed by connecting three or more TFTs in series.

Preferably, the two n-type TFTs of the input circuit are both in a saturation region during operation. The operation refers to a specified operation state of the circuit. By reasonable setting of a width-to-length ratio parameter of the TFT and a bias voltage, the TFTs of the input circuit all work in the saturation region, and the output impedance of the circuit can be increased. Preferably, the amplifier includes first to fourth bootstrap structure units, and the output buffer includes four TFTs. An experiment shows that the amplifier consisting of the four bootstrap structure units and the output buffer that includes four TFTs has a relatively large output signal gain and large bandwidth.

Preferably, referring to FIG. 2, a specific circuit of the TFT-based bootstrap structure amplifier is as follows.

The input circuit is composed of a first TFT T1 and a second TFT T2. The source of the first TFT T1 is connected to the grounding node GND; the drain of the first thin film transistor is connected to the source of the second TFT T2; the drain of the second TFT T2 is connected to the output signal node VO; the gate of the first TFT T1 is connected to an input signal Vin; the gate of the second TFT T2 is connected to a bias voltage Vb;

the output buffer is composed of a third TFT T3, a fourth TFT T4, a fifth TFT T5, and a sixth TFT T6; the drain of the sixth TFT T6 is connected to the input voltage node VDD; the source of the sixth TFT T6 is connected to the drain of the fifth TFT T5; the source of the fifth TFT T5 is connected to the drain of the fourth TFT T4; the source of the fourth TFT T4 is connected to the drain of the third TFT T3; the source of the third TFT T3 is connected to the output signal node VO;

the first bootstrap structure unit is composed of a seventh TFT T7 and a first capacitor C1; the drain and the gate of the seventh TFT T7 are both connected to a first bias voltage node VC1; the source of the seventh TFT T7 is connected to the gate of the third TFT T3 and one end of the first capacitor C1; the other end of the first capacitor C1 is connected to the output signal node VO;

the second bootstrap structure unit is composed of an eighth TFT T8 and a second capacitor C2; the drain and the gate of the eighth TFT T8 are both connected to a second bias voltage node VC2; the source of the eighth TFT T8 is connected to the gate of the fourth TFT T4 and one end of a second capacitor C2; the other end of the second capacitor C2 is connected to the output signal node VO;

the third bootstrap structure unit is composed of a ninth TFT T9 and a third capacitor C3; the drain and the gate of the ninth TFT T9 are both connected to a third bias voltage node VC3; the source of the ninth TFT T9 is connected to the gate of the fifth TFT T5 and one end of a third capacitor C3; the other end of the third capacitor C3 is connected to the output signal node VO;

the fourth bootstrap structure unit is composed of a tenth TFT T10 and a fourth capacitor C4; the drain and the gate of the tenth TFT T10 are both connected to a fourth bias voltage node VC4; the source of the tenth TFT T10 is connected to the gate of the sixth TFT T6 and one end of a fourth capacitor C4; and the other end of the fourth capacitor C4 is connected to the output signal node VO.

Implementation of the present disclosure has the following beneficial effects: the drains and gates of the TFTs of the bootstrap structure units are all connected to the same voltage node; the sources of the TFTs of the bootstrap structure units are connected to the capacitors and the gates of the TFTs in the output buffer; the other ends of the capacitors are connected to the output signal node, and the input circuit is a common-source common-gate circuit. It can be seen that the amplifier increases the voltage through the bootstrap structure units and forms a feedback loop with the output buffer, so as to increase the voltage of the output buffer, thus increasing the circuit gain. The input circuit increases the output impedance of the circuit and the bandwidth. This circuit has a simple structure, low fabrication cost, and wide application range.

In another aspect, the embodiments of the present disclosure provide a chip, including a package and the above-mentioned TFT-based bootstrap structure amplifier. The TFT-based bootstrap structure amplifier is packaged in the package. The package includes a BGA and an SOP. In the case that the chip ensures that the performance meets the requirement, the smaller the package, the better, which is favorable for expanding the application range of the chip.

The chip and the TFT-based bootstrap structure amplifier realize the same functions.

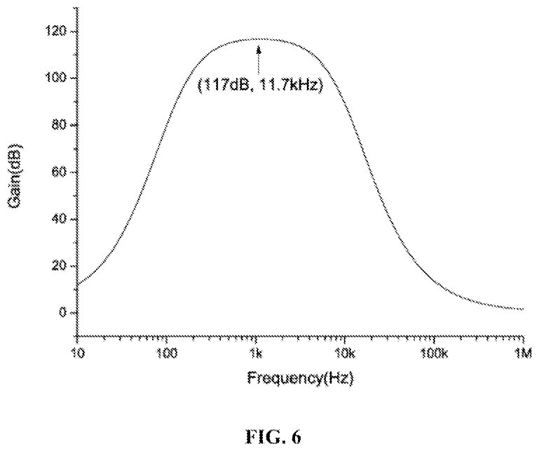

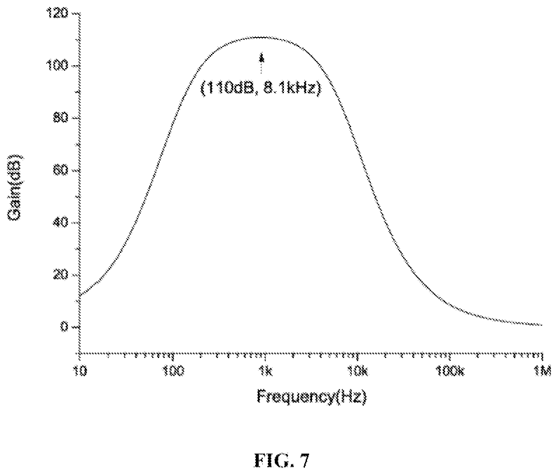

The present disclosure provides another embodiment. The TFT-based bootstrap structure amplifier is subjected to circuit simulation. Simulation results are as shown in FIG. 6. When there is no load, the highest gain obtained is 117 dB, and the −3 dB bandwidth is 11.7 kHz. If the influence of a test load (10 MΩ//16 pF) on the highest gain, simulation results are as shown in FIG. 7. The highest gain obtained is 110 dB, and the −3 dB bandwidth is 8.1 kHz.

The above specifically describes preferred implementations of the present disclosure. However, the creation of the present disclosure is not limited to the embodiments. Those skilled in the art can also make various equivalent deformations or alterations without departing from the spirit of the present disclosure. These equivalent deformations or alterations shall all fall within the scope defined by the claims of the present disclosure.

1. A thin film transistor (TFT)-based bootstrap structure amplifier, comprising an input circuit, an output buffer, and several bootstrap structure units, where in
the bootstrap structure unit comprises a TFT and a capacitor; the drain and the gate of the TFT are both connected to the same voltage node; the source of the TFT is connected to one end of the capacitor; the other end of the capacitor is connected to an output signal node;
the output buffer is formed by connecting several TFTs in series; two ends of the output buffer are respectively connected to an input voltage node and an output signal node;
the source of the TFT in each bootstrap structure unit is connected to the gate of the TFT in one output buffer; and
the input circuit comprises an input signal node, the output signal node, and a grounding node.

2. The TFT-based bootstrap structure amplifier according to claim 1, wherein the TFTs are all n-type TFTs.

3. The TFT-based bootstrap structure amplifier according to claim 1, wherein the TFTs in the bootstrap structure units are in switched-off states during operation.

4. The TFT-based bootstrap structure amplifier according to claim 1, wherein the input circuit is composed of a common-source common-gate circuit.

5. The TFT-based bootstrap structure amplifier according to claim 4, wherein the input circuit comprises two n-type TFTs.

6. The TFT-based bootstrap structure amplifier according to claim 5, wherein the two n-type TFTs of the input circuit are both in a saturation region during operation.

7. The TFT-based bootstrap structure amplifier according to claim 1, wherein the amplifier comprises first to fourth bootstrap structure units, and the output buffer includes four TFTs.

8. The TFT-based bootstrap structure amplifier according to claim 7, wherein
the input circuit is composed of a first TFT and a second TFT; the source of the first TFT is connected to the grounding node; the drain of the first thin film transistor is connected to the source of the second TFT; the drain of the second TFT is connected to the output signal node; the gate of the first TFT is connected to the input signal node; the gate of the second TFT is connected to a bias voltage node;
the output buffer is composed of a third TFT, a fourth TFT, a fifth TFT and a sixth TFT; the drain of the sixth TFT is connected to the input voltage node; the source of the sixth TFT is connected to the drain of the fifth TFT; the source of the fifth TFT is connected to the drain of the fourth TFT; the source of the fourth TFT is connected to the drain of the third TFT; the source of the third TFT is connected to the output signal node;
the first bootstrap structure unit is composed of a seventh TFT and a first capacitor; the drain and the gate of the seventh TFT are both connected to a first bias voltage node; the source of the seventh TFT is connected to the gate of the third TFT and one end of the first capacitor; the other end of the first capacitor is connected to the output signal node;
the second bootstrap structure unit is composed of an eighth TFT and a second capacitor; the drain and the gate of the eighth TFT are both connected to a second bias voltage node; the source of the eighth TFT is connected to the gate of the fourth TFT and one end of a second capacitor; the other end of the second capacitor is connected to the output signal node;
the third bootstrap structure unit is composed of a ninth TFT and a third capacitor; the drain and the gate of the ninth TFT are both connected to a second bias voltage node; the source of the ninth TFT is connected to the gate of the fifth TFT and one end of a third capacitor; the other end of the third capacitor is connected to the output signal node;
the fourth bootstrap structure unit is composed of a tenth TFT and a fourth capacitor; the drain and the gate of the tenth TFT are both connected to a fourth bias voltage node; the source of the tenth TFT is connected to the gate of the sixth TFT and one end of a fourth capacitor, and the other end of the fourth capacitor is connected to the output signal node.

9. A chip, comprising a package and the TFT-based bootstrap structure amplifier according to claim 1, wherein the TFT-based bootstrap structure amplifier is packaged in the package.
